(19) United States
(12) Patent Application Publication
(10) Pub. No.: US 2010/0327303 A1
(43) Pub. Date: Dec. 30, 2010

(54) Light-emitting diode lamp with uniform resin coating

(76) Inventor: Yung Pun Cheng, Macau (CN)

Correspondence Address: BAKER & MCKENZIE LLP;PATENT DEPARTMENT, 2001 ROSS AVENUE, SUITE 2300, DALLAS, TX, 75201, US

(21) Appl. No.: 12/819,110

(22) Filed: Jun. 18, 2010

(30) Foreign Application Priority Data
Jun. 24, 2009 (CN) 200910146354.6

(51) Int. Cl. H01L 33/52; H01L 21/56; B22D 19/08

(52) U.S. Cl. 257/98; 438/27; 249/83; 257/E33.059; 257/E21.502

(57) ABSTRACT

LED lamps with a conformally coated LED chip and methods of manufacturing the same provides for LEDs having predictable color temperature. A conformally coated LED chip includes an LED chip with a conformal resin layer disposed over a portion of the LED chip. The LED lamp may have the characteristics of stable color temperature, substantially even and uniform distribution of illumination, and wide illumination angle.

### CROSS-REFERENCE TO RELATED APPLICATIONS

This patent application relates and claims priority to Chinese patent application 200910146354.6 filed Jun. 24, 2009, which is herein incorporated by reference for all purposes.

### TECHNICAL FIELD

This disclosure relates generally to light-emitting diodes (LEDs) and, more specifically, to LED devices with wide illumination angles and substantially uniform illumination intensity and methods for manufacturing the same.

### BACKGROUND

With the developments in light-emitting diode (LED) technologies, high-powered LEDs are more frequently designed for lighting applications, for example, household lighting applications. In contrast with the conventional light sources, such as incandescent lights, LEDs (and lamps utilizing LEDs) possess various advantages, such as sufficient brightness, low energy consumption, high reliability, long lifetime, etc. These lead to the perspective of its wide application in the lighting field.

With respect to high-powered LEDs, packaging is an important factor with respect to LED performance. For high-powered LEDs, LED chips are usually mounted to a substrate because high-powered LEDs (e.g., 0.5 watts or above) generate a substantial amount of heat which should be directed away from the LED chip. A silver epoxy or silver paste may be used to adhere (e.g., solder) the LED chip onto the substrate. Small gold wires may then connect the LED chips to external electrical terminals to supply power to the LED chip. Finally, a layer of phosphor coating may be used to coat the LED chip to change the output light of the LED from blue to white. The finished LED lamp product may also include a heat sink. This type of packaging, however, has drawbacks such as relatively high cost, narrow illumination angle, and non-uniform color temperature.

### BRIEF SUMMARY

The disclosed embodiments provide LEDs with uniform resin coating, LED lamps including LEDs with a uniform resin coating, and a method for manufacturing the same. Such LEDs and LED lamps are made using a mold. One benefit of using a mold filled with resin for LEDs, for manufacturing processes for manufacturing LEDs, or for LED lamps is to create a substantially even and substantially uniform resin coating over LED chips.

According to an aspect, a LED module is disclosed. The LED module has a LED chip element and a resin coating substantially uniformly distributed over at least three surfaces of the LED chip element.

According to another aspect, a LED lamp is disclosed. The LED lamp has a LED chip element and a resin coating substantially uniformly distributed over at least three surfaces of the LED chip element. The LED chip element is mounted to a substrate and electrical terminals are connected to the LED chip element.

According to another aspect, a method for manufacturing a LED lamp is disclosed. A LED chip is mounted to a support and a mold portion having a recessed area is provided and positioned such that the recessed area is facing in an upward direction. A portion of the recessed area is filled with a resin. The LED chip is inserted into the recessed area of the mold portion such that the LED chip is substantially evenly coated with the resin.

According to another aspect, a mold for coating a LED chip element is disclosed. The mold has a recessed area and the dimensions of the LED chip element are smaller than the dimensions of the recessed area such that the LED chip element may fit inside the recessed area.

### BRIEF DESCRIPTION OF THE DRAWINGS

FIG. 1A is a schematic diagram illustrating a close-up view of a conventional LED;

FIG. 1B is a schematic diagram illustrating a cross-sectional view of the conventional LED of FIG. 1A;

FIGS. 2A, 2B, and 2C are a schematic diagrams illustrating another conventional LED;

FIG. 3A is a close-up view of an embodiment of an LED;

FIG. 3B is a schematic diagram illustrating a cross-sectional view of the LED of FIG. 2A, in accordance with the present disclosure;

FIG. 4A is schematic diagram of a chip mounted on a support, in accordance with the present disclosure;

FIG. 4B is a schematic diagram illustrating a cross-sectional view of an embodiment of a mold without an LED chip disposed therein, in accordance with the present disclosure;

FIG. 4C is a schematic diagram illustrating a view of the embodiment shown in FIG. 4B, in accordance with the present disclosure;

FIG. 4D is a schematic diagram illustrating a cross-sectional view of an embodiment of an LED lamp, in accordance with the present disclosure;

FIG. 5 is a schematic diagram illustrating illumination angles of an embodiment of an LED lamp, in accordance with the present disclosure;

FIG. 6 is a schematic diagram illustrating a flow chart of the method of manufacturing LED lamps, in accordance with the present disclosure;

FIGS. 7A-7D are schematic diagrams of three-dimensional views of molds for coating a LED chip element, in accordance with the present disclosure.

### DETAILED DESCRIPTION

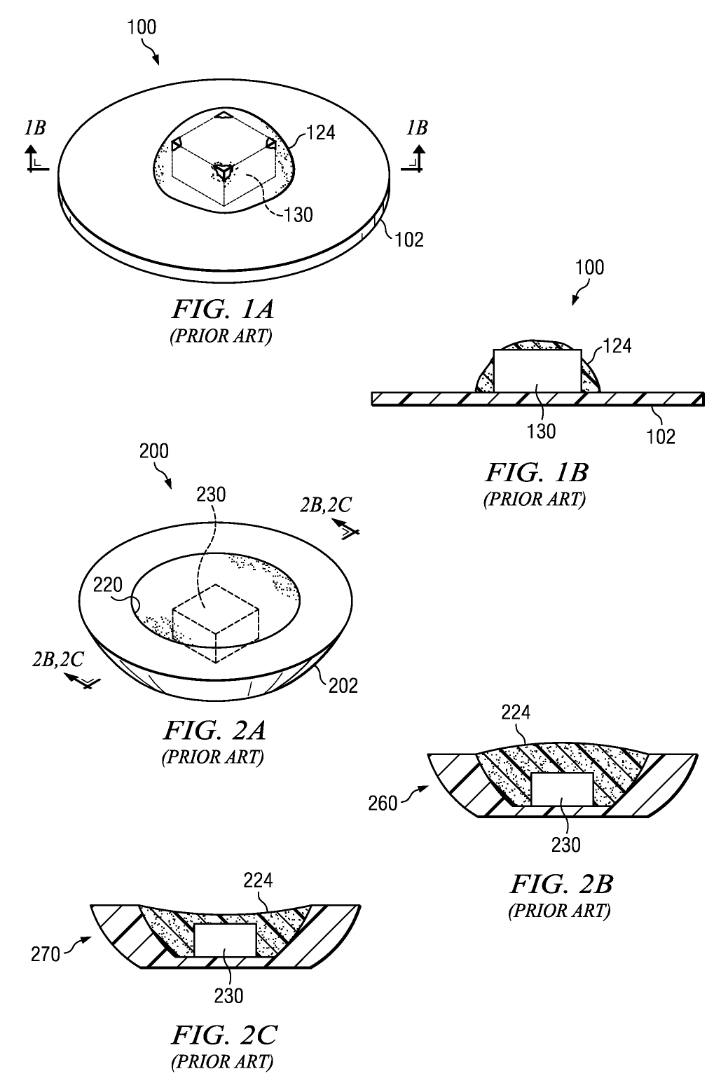

FIG. 1A is a schematic diagram illustrating a conventional coated LED 100 and FIG. 1B is a schematic diagram illustrating a cross-sectional view of the coated LED 100 along line 1B. The coated LED 100 is positioned on a plane 102 for purposes of this illustration only, but a typical coated LED 100 would be attached to electrodes and positioned on a substrate. As discussed above, phosphor is used to coat LEDs in order to change the light emitted from blue to white. A phosphor is applied to an LED chip by first mixing the phosphor with a resin, such as silicon rubber, and dispensing this resin 124 in the form of drops onto the surfaces of an LED chip 130. As illustrated in FIGS. 1A and 1B, such dispensing, due to the weight and impact of the drops resin 124 onto the surface of the LED chip 130, leads to uneven distribution of resin. It is difficult to control the volume of resin 124 dropped onto the LED chip 130 because the resin 124 is viscous and, thus, a long tail of fluid follows the drops.

Furthermore, dispensing devices are typically unable to control with precision the position of drops and, thus, the thickness of the resin 124 applied to exposed surfaces of LED chips is non-uniform. Indeed, some surfaces of an LED chip 130 may not be covered at all with this method. Uneven distribution of resin 124 on LED chips 130 results in difficulty in controlling the color temperature. Non-uniform resin 124 application typically results in non-uniform illumination. Furthermore, the illumination angle of an LED may be limited.

The difficulties in controlling color temperature may require a measurement or binning step for measuring the exact shade coming out of an LED and sorting the products into bins of similar colors. This extra “binning” step adds time and complexity to an LED manufacturing process.

FIG. 2A is a schematic diagram of an embodiment of another conventional process 200 for creating a coated LED chip. An apparatus 202 contains a hole 220. An LED chip 230 is placed in the hole 220 with the light producing side (or, the “top”) of the LED 230 facing in an upwards direction. A fluid (not shown) is used to fill the hole, unevenly covering the top and sides of the LED 230 because the hole 220 is at least partially over- or under-filled. Even small discrepancies make a large difference in color.

FIGS. 2B and 2C are schematic diagrams illustrating the uneven coverage 260, 270 of the LED chip 230 resulting from the process 200 described in relation to FIG. 2A. FIG. 2B is a coated LED chip 260 resulting from an over-filled hole 220. The LED chip 230 is coated with a fluid or resin 224. The top of the resin coating 224 is bowed out, resulting in an uneven coverage over the top of the LED 230. FIG. 2C is a coated LED chip 270 resulting from an under-filled hole 220. The top of the resin coating 224 is bowed in, also resulting in uneven coverage over the top of the LED 230.

The uneven coverage from the filling process described in FIGS. 2A-2C also lead to an extra “binning” step, adding time and complexity to an LED manufacturing process.

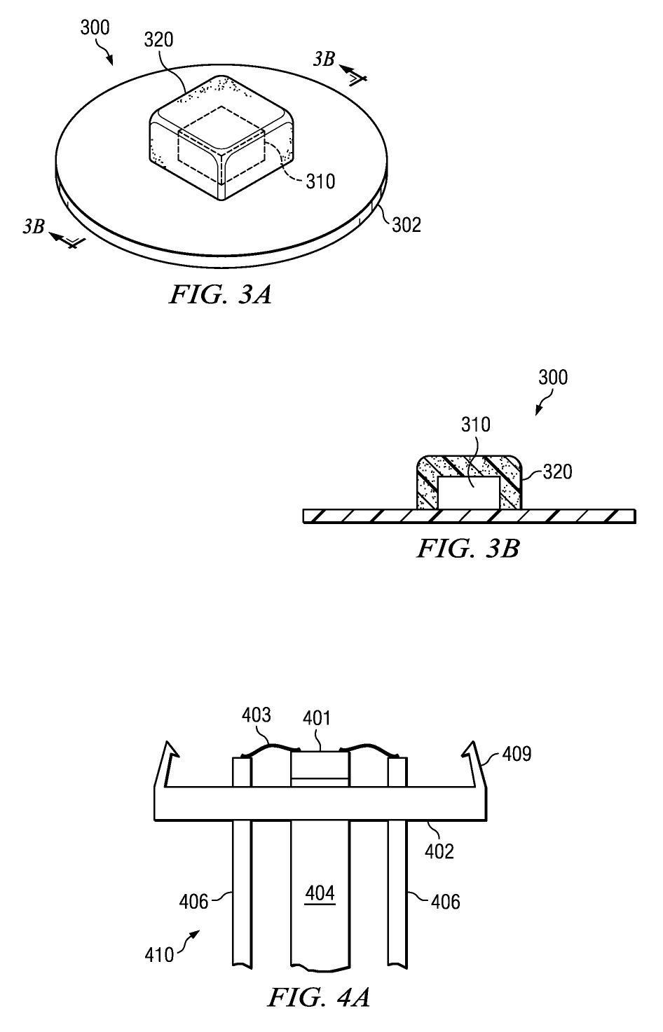

FIG. 3A is a schematic diagram of an embodiment of a coated LED 300 and FIG. 3B is a schematic diagram of a cross-sectional view of the coated LED 300 along line 3B. An LED 310 is coated with a conformal resin coating 320. In an embodiment, the conformal resin coating 320 comprises a silicon rubber. In another embodiment, the conformal resin coating 320 is mixed with a fluorescent powder (e.g., phosphor).

The conformal resin coating 320 is distributed substantially evenly and uniformly over the surfaces of the LED 310. As can be seen by the cross sectional view in FIG. 3B, the thickness of the conformal resin coating 320 is substantially the same around the LED 310. The coated LED 300 is positioned on a plane 302 for purposes of this illustration only, but a typical coated LED 300 would be attached to electrodes with wires and positioned on a substrate. The substantially even and substantially uniform distribution may allow for enhanced control over the color temperature of the LEDs, more uniform illumination, and reduced limitations on the angle of illumination of an LED.

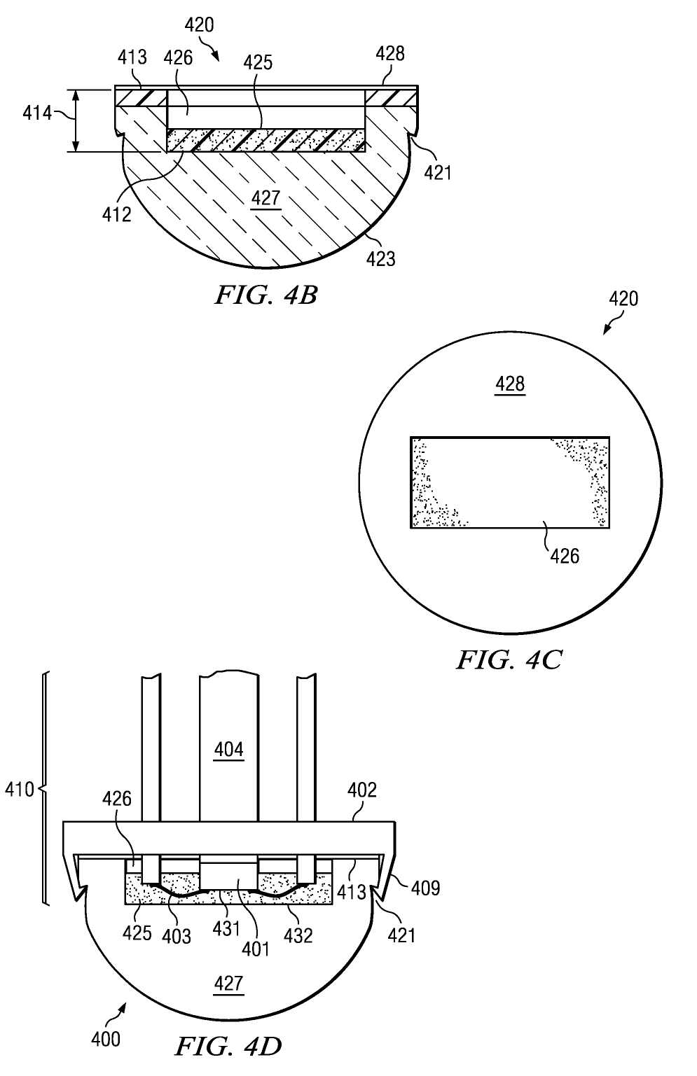

FIGS. 4A-4D are schematic diagrams illustrating different aspects of an embodiment of an LED lamp 400 (shown in full in FIG. 4D) including a coated LED 401 with a substantially even and substantially uniform coating of resin.

FIG. 4A is a schematic diagram illustrating an embodiment of a base portion 410 of an LED lamp 400. An LED chip 401 is mounted on a support structure 404. The support structure 404 functions as a substrate. In an embodiment, the light producing side (or, the “top”) of the LED 401 faces away from the base portion 410—i.e., the bottom portion of the LED is connected to the base portion 410.

In an embodiment, the LED chip 401 is adhered to the support structure 404 using a silver epoxy or silver paste. In an embodiment, the LED chip 401 is connected to an anode and cathode 406 via wires 403 (e.g., gold wires).

In another embodiment, the support structure 404 comprises a locking arm 402. Support structure 404 may be made of copper. The anode and cathode 406 may be made of silver plated iron. The locking arm 402 may be made of plastic. In an embodiment, during manufacturing, when the locking arm is made by hardening or solidifying molten plastic and the anode and cathode 406 and the support structure 404 may extend longitudinally through the locking arm 402 before the molten plastic has solidified resulting in the anode and cathode 406 being connected the support structure 404 when the plastic solidifies.

Locking arm 402 may comprise at least one hooking portion 409 operable to engage the base portion 410 of the LED lamp 400 to a mold portion 420 of the LED lamp 400, which will be discussed with greater detail with respect to FIG. 4B. Other embodiments contemplate connecting a base portion 410 with a mold portion 420 in other fastening or connecting mechanisms well known in the art.

FIG. 4B is a schematic diagram illustrating a cross-sectional view of an embodiment of a mold portion 420 for the LED lamp 400 shown in FIG. 4D. In this embodiment, the mold portion 420 comprises generally a half-sphere shape. In other embodiments, the mold portion 420 may comprise a cube, rectangular box, or any other shape or configuration, including irregular shapes. In an embodiment, the mold portion 420 is made of plastic material and may be transparent. The mold portion 420 includes a recessed area 426 defined in a surface 413. The recessed area 426 may comprise a variety of three dimensional shapes including, but not limited to, a cubic shape, a rectangular three-dimensional shape, a half spherical shape, etc.

In an embodiment, during manufacturing, the mold portion 420 is inverted so that the recessed area 426 is facing upwards, as shown in FIG. 4B. In this inverted orientation, the surface 413 may be considered the “top” surface of the inverted mold 420 and the surface 423 may be considered the “bottom” surface of the inverted mold 420. When the mold 420 is inverted, the recessed area 426 may be filled with a resin 425 (e.g. silicon rubber) that may be mixed with fluorescent powder (e.g., phosphor). In an embodiment, the area of a bottom surface 412 of the recessed area 426 is no greater than one-third of the area of the top surface 413 of the container mold portion 420. In another embodiment, the depth 414 of the recessed area 426 is no greater than 6 millimeters (e.g., 5, 4, or 3 millimeters, etc.). When the recessed area 426 is filled with silicon rubber containing fluorescent powder (including phosphors), some space may be reserved for the insertion of the support 404 for mounting the LED chip (discussed in more detail below). The amount of the resin 425 filled into the recessed area 426 may be controlled as well. In an embodiment, no greater than 99% of the volume of the recessed area 426 is filled with resin 425 (for example, 98%, 95%, 90%, etc.).

Still referring to FIG. 4B, in an embodiment, the mold portion 420 comprises a pit area 421 on the outer bottom surface of the inverted mold 420. The pit area 421 may be used in conjunction with the hooking section 409 of the locking arm 402 of the base portion 410 (discussed in reference to FIG. 4A) for locking the bottom portion 410 to the mold portion 420 by using the locking arm 402 and fastening it to fit in the pit area 421. The locking arm 402 fastens the base portion 410 to the mold portion 420. The pit area 421 may be a latch that cooperates with the hooking section 409 to connect the mold portion 420 to the base portion 410.

In an embodiment, the bottom surface 413 of the mold portion 420 is coated with a reflective coating 428. The reflective bottom coating 428 allows for greater dispersion of light from an LED element positioned in the recessed area 426 (discussed below in reference to FIG. 4D).

FIG. 4C is a schematic diagram illustrating a view looking at the mold portion 420 from the perspective of the bottom surface 413 (i.e., looking down at the mold portion 420 as it is pictured in FIG. 4B). The reflective bottom coating 428 covers the bottom surface 413 of the mold portion 420. As shown in FIG. 4C, the recessed area 426 of the bottom of the mold portion 420 is not coated with the reflective coating 428.

FIG. 4D is a schematic diagram illustrating an embodiment of an LED lamp 400 including base portion 410 and mold portion 427. FIG. 4D illustrates the components from FIGS. 4A-4C assembled. The bottom portion 410 is inverted and the LED 401 is inserted into the recessed portion 426 of the mold 420. In an embodiment, the “top” portion of the LED 401 is inserted first—i.e., the “top” portion of the LED 401 faces towards the “bottom” portion of the inverted mold 420.

Since the recessed portion 426 of the mold 420 contains resin 425, the LED 401 is coated with the resin 425 once inserted into the recessed area 426 of the mold 420. In an embodiment, the “top” portion of the LED 401 and side portions of the LED 401 are covered with the resin. The “bottom” portion of the LED 401 is connected with the base portion 410 and may not be covered with the resin material 425. When the recessed portion 426 of the mold 420 is filled with resin 425 while the “top” portion of the LED 401 faces the bottom portion of the inverted mold 420, more control over the thickness, evenness of the depth of the resin 425 over the “top” surface of the LED 401 is achieved. Even if the recessed portion 426 of the mold 420 is over- or under-filled, the depth of the resin 425 over the “top” surface of the LED may be substantially controlled because the distance between the “top” surface of the LED 420 and the “bottom” surface of the recessed area 432 may be substantially controlled during manufacturing. The most light in the LED comes from the “top” portion of the LED and, thus, the temperature and color of the LED may be controlled. Having a more well-controlled temperature and color of the LED may result in a more efficient LED manufacturing process, as the measurement and binning processes may be substantially reduced or, in an embodiment, eliminated.

When the shape and dimensions of the recessed area 426 are adjusted, so are the dimension and shape of the resin coating on the LED 401. In effect, the uniformity of the thickness and the shape of resin 425 on the chip 401 may be controlled, thereby allowing for control of the color temperature of light for the LED chip 401 to be coherent, stable, and controllable. This enables the effect of illumination to be distributed substantially evenly.

In an embodiment, the distance between the surface 431 of the chip 401 and the bottom 432 of the recessed area 426 is kept within the range of 0.3-1 millimeters (e.g., 0.3 mm, 0.5 mm, 0.8 mm, 1 mm, etc.). Because the volume of the recessed area 426 (including, but not limited to the depth, width, and length of the recessed area 426) is controllable, the amount of resin 425 on any surface of the LED 401 is also controllable, which, in turn, also yields controllability over the color temperature of the light and the uniformity of the illumination.

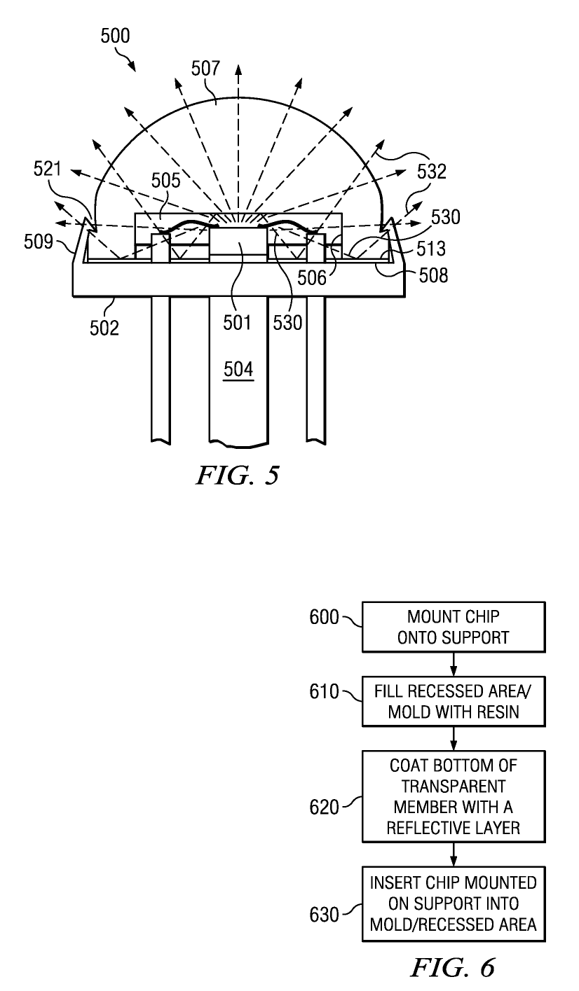

FIG. 5 is a schematic diagram illustrating the illumination angles of an embodiment of an LED lamp 500. A reflective layer 508 is coated onto the bottom 513 of a mold portion 507. In an embodiment, prior to locking the support 504 to the mold portion 507 with the locking arm 502, the hooking section 509 of the locking arm 502, and the pit area 521 of the mold portion 507, the reflective layer 508 is coated onto the bottom 513 of the mold portion 507 by electroplating and heat transfer. Electroplating is a plating process using electrical current to reduce cations of a desired material from a solution and coat a conductive object with a thin layer of the material, such as a metal. The heat transfer is a process similar to ironing a picture on a t-shirt. Essentially, a highly reflective material 508 is “ironed” onto the bottom surface 513 via heat transfer. The locking arm 502 then may be put into place to ensure that the support 504 with the LED 501 is secured to the mold portion 507.

In an embodiment, both ends of the locking arm 502 have hooking sections 509 which cooperate with pits 521 provided on the sides of the mold to mount the support 504 having the LED chip 501 with the mold 507.

Applying a reflective layer 508 allows for more efficient use of light. In an embodiment, the mold portion 507 is transparent and plastic. Thus, the light emitted after connecting the LED chip 501 to the power source projects out of the mold portion 507. Some light emitted from the LED chip 501 is emitted in a downward direction 530 and the reflective layer 508 reflects this light, redirecting the light 532 out of the mold portion 507. This increases the illumination angle and substantially eliminates dead angles from the LED lamp 500, enlarging the illumination angle and rendering the light emitted from the mold 507 to be even more uniform.

FIG. 6 is a flow chart of an embodiment of a method of manufacturing a LED chip with a uniform resin coating. At step 600, an LED chip is mounted onto a support. In an embodiment, the chip may be disposed onto the support by, e.g., welding or any other way known in the art for mounting chips on support members. At step 610, a mold portion is inverted and a recessed area of the mold portion is filled with a resin. In an exemplary embodiment, the resin is a silicon rubber. In another embodiment, the resin is mixed with fluorescent powder (e.g., phosphor).

In an embodiment, an optional step 620 is performed and the bottom of the mold portion is coated with a reflective layer. In an embodiment, the reflective layer is a reflective paint applied to the bottom of the mold portion. In another embodiment, the reflective layer is a reflective material (e.g. paper or plastic) sheet laid over the bottom of the mold portion. The reflective layer does not cover a recessed area of the mold portion.

Finally, in step 630, the mold portion is positioned so that the recessed area is facing upwards. Then the support is inverted and the chip is inserted into the recessed area of the mold. In an embodiment, the process further comprises a step for curing the resin (e.g., in an oven) by any methods known in the art.

### Mold for Coating a Light Emitting Diode Chip Element

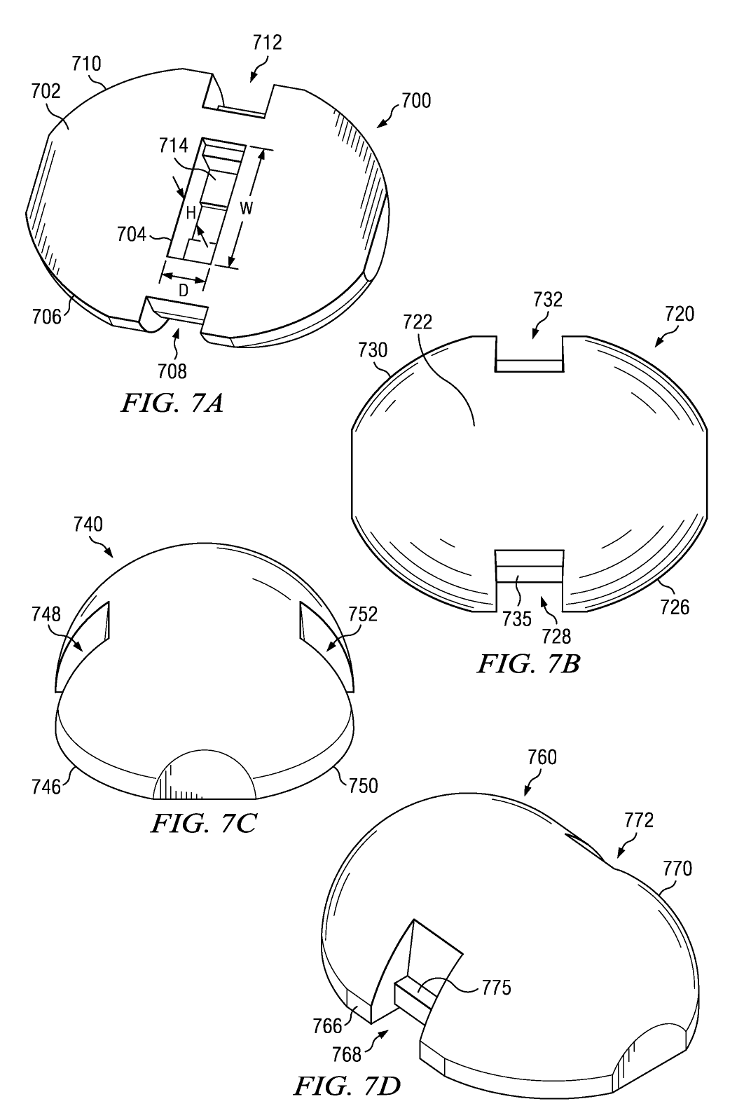

FIG. 7A is a schematic diagram of a three-dimensional (3D) view of a mold 700 for coating a light emitting diode chip element. Mold 700 includes a first surface 702 having a recessed area 704 defined in the first surface 702, a first edge portion 706, and a first recessed portion 708 defined in the first edge portion 706. In an embodiment, the mold 700 also includes a second edge portion 710 and a second recessed portion 712 defined in the second edge portion 710. The first edge portion 706 may be partially defined by the first surface 702 and may also be partially defined by a second surface (not shown). Further, the second edge portion 710 may be partially defined by the first surface 702 and may also be partially defined by a second surface (not shown).

The mold 700 is operable to function as a mechanism for coating a light emitting diode element. A light emitting diode coated by the mold 700 element has a height, width, and depth. In an embodiment, the recessed area 704 of the mold 700 is a rectangular shape having a height H, width W, and depth D. Although a rectangular three-dimensional shape is shown in FIG. 7A for the recessed area 704, one skilled in the art would appreciate that the recessed area 704 may comprise a variety of three dimensional shapes including, but not limited to, a cubic shape, a rectangular three-dimensional shape, a half spherical shape, etc.

The height H, width W, and depth D of the recessed area 704 are at least larger than the height, width, and depth of the LED element to be coated in the mold 700 (such that the LED element may fit inside the recessed area 704 of the mold 700). In an embodiment, the height, width, and depth dimensions of the LED are 99% of the height H, width W, and depth D of the recessed area 704 of the mold 700. In another embodiment, the height, width, and depth dimensions (H, W, and D) of the recessed area 704 of the mold 700 are within the range of 2 to 10 times the thickness of the LED element. In another embodiment, the height H of the recessed area 704 is between 0.3 and 1 millimeters larger than the height of an LED, allowing for the distance between the bottom portion 714 of the recessed area and the bottom portion of the LED is between 0.3 and 1 millimeters.

FIG. 7B is a schematic diagram of a 3D view of a mold 720 for coating a light emitting diode chip element. Mold 720 includes a first surface (not shown) having a recessed area (not shown), a first edge portion 726, and a first recessed portion 728 defined in the first edge portion 726. In an embodiment, the mold 720 also includes a second edge portion 730 and a second recessed portion 732 defined in the second edge portion 730. In an embodiment the first surface (not shown) of the mold 720 is substantially planar and a second surface 722 that is curved. The first edge portion 726 may be partially defined by the first surface (not shown) and may also be partially defined by the second surface 722. Further, the second edge portion 730 may be partially defined by the first surface (not shown) and may also be partially defined by the second surface 722.

FIGS. 7C and 7D are schematic diagrams of three-dimensional views of molds 740, 760 (respectively) for coating a light emitting diode chip element. Molds 740, 760 include a first surface (not shown); a recessed area (not shown); a first edge portion 747, 766; and a first recessed portion 748, 768 defined in the first edge portion 746, 766 (respectively). In an embodiment, the molds 740, 760 also include a second edge portion 750, 770 and a second recessed portion 752, 772 defined in the second edge portion 750, 770 (respectively).

In an embodiment, the molds 700, 720, 740, and 760 are made of a transparent plastic material (e.g., polycarbonate, glass, epoxy, any hard transparent material). The recessed portions 708/712, 728/732, 748/752, and 768/772 of molds 700, 720, 740, and 760 may also include a latch or ledge (e.g., latch/ledge 735 of FIG. 7B or 775 of FIG. 7D) for coupling with a light emitting diode support having a latching arm. The latching arm and latch or ledge 735, 775 may be coupled together such that the mold 700, 720, 740, 760 is operable for use as a cover for an LED element fit inside the recessed area 704 of a mold 700, 720, 740, 760.

While various embodiments in accordance with the principles disclosed herein have been described above, it should be understood that they have been presented by way of example only, and not limitation. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” the claims should not be limited by the language chosen under this heading to describe the so-called field. Further, a description of a technology in the “Background” is not to be construed as an admission that certain technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A light emitting diode module, the module comprising:
a light emitting diode chip element having a coated portion and an exposed portion; and
a conformal resin layer disposed over the coated portion of the light emitting diode chip element.

2. The light emitting diode module of claim 1, wherein the conformal resin layer comprises a silicon rubber.

3. The light emitting diode module of claim 1, wherein the conformal resin layer comprises a silicon rubber mixed with a fluorescent powder.

4. A light emitting diode lamp, the lamp comprising:
a light emitting diode chip element having a coated portion and an exposed portion;
a conformal resin layer disposed over the coated portion of the light emitting diode chip element;
a support structure, wherein the light emitting diode chip element is mounted on the support structure, the exposed portion of the light emitting element being proximate to a mounting surface of the support structure; and
electrical terminals electrically connected to the light emitting diode chip element.

5. The light emitting diode lamp of claim 4, further comprising:
a mold portion connected to the support structure, the mold portion comprising a transparent plastic material; and
a reflective sheet, the reflective sheet disposed on a bottom portion of the mold portion.

6. The light emitting diode lamp of claim 4, wherein the light emitting diode chip element has a first height dimension, a first width dimension, and a first depth dimension, and wherein the mold portion comprises:
a first surface having a recessed area, wherein the recessed area has a second height dimension, a second width dimension, and a second depth dimension;
a first edge portion; and
a first recessed portion defined in the first edge portion;
wherein the first height, width, and depth dimensions are smaller than the second height, width, and depth dimensions, respectively; and
wherein the light emitting diode chip element is disposed in the recessed area.

7. The light emitting diode lamp of claim 6, further comprising a base portion, wherein the base portion comprises the support structure and a locking arm having at least one hooking section, and wherein the hooking section is operable to connect the base portion to the mold portion.

8. The light emitting diode lamp of claim 6, wherein the base portion comprises a half-sphere shape.

9. The light emitting diode lamp of claim 7, wherein the mold portion further has a second recessed portion defined in a second edge portion of the mold portion.

10. The light emitting diode lamp of claim 9, wherein the mold portion has at least one latch for coupling with the hooking section of the locking arm.

11. A mold for applying a conformal coating to a portion of a light emitting diode chip element, the light emitting diode chip element having a first height dimension, a first width dimension, and a first depth dimension, the mold comprising:
a first surface having a recessed area, wherein the recessed area comprises a shape having a second height dimension, a second width dimension, and a second depth dimension;
a first edge portion; and
a first recessed portion defined in the first edge portion;
wherein the first height, width, and depth dimensions are smaller than the second height, width, and depth dimensions, respectively; and
wherein the light emitting diode chip element is disposed in the recessed area.

12. The mold of claim 11, wherein the first height, width, and depth dimensions are 99% of the second height, width, and depth dimensions, respectively.

13. The mold of claim 11, wherein the second height, width, and depth dimensions are within a range of 2 to 10 times the thickness of the first height, width, and depth dimensions, respectively.

14. The mold of claim 11, wherein the second height dimension is between 0.3 and 1 millimeters larger than the first height dimension.

15. The mold of claim 11, wherein the first surface is substantially planar.

16. The mold of claim 11, wherein the first edge portion is partially defined by the first surface.

17. The mold of claim 11, wherein the mold comprises a transparent plastic material.

18. The mold of claim 11, wherein the mold further comprises:
a second edge portion; and
a second recessed portion defined in the second edge portion.

19. The mold of claim 11, wherein the first and second recessed portions each comprise a latch operable for coupling with a locking arm of a light emitting diode support structure.

20. The mold of claim 11, wherein the shape of the recessed area comprises a rectangular shape.

21. The mold of claim 11, wherein the shape of the recessed area comprises a half sphere shape.

22. A method for manufacturing a light emitting diode lamp, the method comprising:
mounting a light emitting diode chip onto a support structure;
providing a mold portion having a first surface and a second surface, wherein a recessed area is defined in the first surface;
positioning the mold portion such that the recessed area is facing in an upward direction;
filling a portion of the recessed area with a resin;
orienting the support structure such that the light emitting diode chip is inserted into the recessed area.

23. The method of claim 22, further comprising:
providing a reflective sheet;
disposing the reflective sheet on the bottom of the mold portion prior to inserting the light emitting diode chip into the recessed area.

24. The method of claim 22, further comprising:
curing the resin in an oven.
